(19) United States
(12) Patent Application Publication
(10) Pub. No.: US 2026/0274677 A1
(43) Pub. Date: Sep. 17, 2026

(54) ANISOTROPIC GRAPHITE COMPOSITE AND MANUFACTURING METHOD THEREFOR

(71) Applicant: KANEKA CORPORATION, Osaka (JP)

(72) Inventor: Kan FUJIHARA, Osaka (JP)

(73) Assignee: KANEKA CORPORATION, Osaka (JP)

(21) Appl. No.: 19/474,545

(22) PCT Filed: Apr. 9, 2024
(86) PCT No.: PCT/JP2024/014349

§ 371 Date: Oct. 10, 2025

(30) Foreign Application Priority Data
Apr. 14, 2023 (JP) 2023-066692

(51) Int. Cl. C01B 32/21; C09K 5/14

(52) U.S. Cl. CPC C01B 32/21; C09K 5/14; C01P 2004/03; C01P 2006/32

(57) ABSTRACT

An object is to provide an anisotropic graphite composite having superior heat transfer efficiency. The object is attained by an anisotropic graphite composite (100) in which (a) anisotropic graphite (10) having graphite layers whose respective crystal orientation planes (11) are parallel to an X-Y plane, and a (b) bonding layer (20) containing a metal and/or a resin are alternately stacked in a Z-axis direction, and are bonded to each other, the composite (100) having a thermal resistance value of not more than 10 mm²K/W measured on a surface parallel to an X-Z plane or a Y-Z plane.

### TECHNICAL FIELD

The present invention relates to an anisotropic graphite composite and a method of producing the anisotropic graphite composite.

### BACKGROUND ART

Graphite is widely used as an element for effectively transferring and dissipating heat produced in electronic equipment and devices.

Anisotropic graphite in particular has high thermal conductivity. Anisotropic graphite has graphite structures in which six-membered rings are joined by covalent bonds. The graphite structures are joined by Van der Waals forces. Anisotropic graphite reduces or prevents the occurrence of hot spots in electronic equipment or an electronic part which acts as a heat source. Anisotropic graphite is useful as a heat transmitting element which efficiently transmits heat from a heat source to a cooling apparatus.

Anisotropic graphite tends to be structurally brittle and prone to fracture. To address this problem concerning strength, a technique has been proposed in which a composite of anisotropic graphite in which anisotropic graphite and a layer made of metal, resin, and the like are stacked is used as a heat transmitting element. For example, Patent Literature 1 discloses a technique for forming an inorganic material layer on a surface of anisotropic graphite.

### CITATION LIST

### Patent Literature

### Patent Literature 1

Japanese U.S. Pat. No. 5,930,604

### SUMMARY OF INVENTION

### Technical Problem

However, conventional anisotropic graphite composites as described above had room for improvement in terms of heat transfer efficiency.

In view of these circumstances, an object of an aspect of the present invention is to provide an anisotropic graphite composite having superior heat transfer efficiency and a method of producing the anisotropic graphite composite.

### Solution to Problem

Through diligent research in order to attain the above object, the inventors of the present invention arrived at the present invention. That is, according to an embodiment of the present invention, an anisotropic graphite composite is a composite of graphite including (a) anisotropic graphite and (b) a bonding layer containing a metal and/or a resin, the (a) anisotropic graphite having graphite layers whose respective crystal orientation planes are parallel to an X-Y plane, given an X-axis, a Y-axis orthogonal to the X-axis, and a Z-axis perpendicular to the X-Y plane, the (a) anisotropic graphite and the (b) bonding layer containing the metal and/or the resin being alternately stacked in a direction of the Z-axis and being bonded to each other, the composite having a thermal resistance value of not more than 10 mm²K/W measured on a surface parallel to an X-Z plane or a Y-Z plane.

According to another embodiment of the present invention, a method is a method of producing an anisotropic graphite composite including (a) anisotropic graphite and a (b) bonding layer containing a metal and/or a resin, the (a) anisotropic graphite having graphite layers whose respective crystal orientation planes are parallel to an X-Z plane, given an X-axis, a Y-axis orthogonal to the X-axis, and a Z-axis perpendicular to the X-Y plane, the method including: a bonding step of alternately stacking the (a) anisotropic graphite and the (b) bonding layer containing the metal and/or the resin in a direction of the Z-axis, and bonding them to each other; a cutting step of cutting an obtained bonded body; and a surface peeling step of peeling off a surface parallel to an X-Z plane or a Y-Z plane of the cut bonded body obtained in the cutting step.

### Advantageous Effects of Invention

With an embodiment of the present invention, it is possible to provide an anisotropic graphite composite having superior heat transfer performance and superior long-term reliability as a heat transmitting element, and a method of producing the anisotropic graphite composite.

### BRIEF DESCRIPTION OF DRAWINGS

FIG. 1 is a schematic diagram illustrating an outline of the structure of an anisotropic graphite composite in accordance with an embodiment of the present invention.

FIG. 2 is a diagram depicting an image of a surface of an anisotropic graphite composite in accordance with an example of the present invention and an image of a surface of an anisotropic graphite composite in accordance with a comparative example, observed by using a scanning electron microscope (SEM).

FIG. 3 is a diagram depicting an image of a cut surface of a bonded body of anisotropic graphite in accordance with the comparative example of the present invention.

### DESCRIPTION OF EMBODIMENTS

The following description will discuss embodiments of the present invention. The present invention is not, however, limited to these embodiments. The present invention is not limited to the configurations described below, but may be altered within the scope of the claims by a person skilled in the art. The present invention also encompasses, in its technical scope, any embodiment derived by combining technical means disclosed in differing embodiments and Examples. Further, it is possible to form a new technical feature by combining the technical means disclosed in the respective embodiments. All academic and patent documents cited in the present specification are incorporated herein by reference. Any numerical range expressed as “A to B” in the present specification means “not less than A and not more than B (i.e., a range from A to B which includes both A and B) ” unless otherwise stated.

### 1. Anisotropic Graphite Composite

An anisotropic graphite composite in accordance with an embodiment of the present invention (which may be referred to as the “present composite” below) is a graphite composite including (a) anisotropic graphite and (b) a bonding layer containing a metal and/or a resin, the anisotropic graphite having graphite layers whose respective crystal orientation planes are parallel to an X-Y plane, given an X-axis, a Y-axis orthogonal to the X-axis, and a Z-axis perpendicular to the X-Y plane, the (a) anisotropic graphite and the (b) bonding layer containing the metal and/or the resin being alternately stacked in a direction of the Z-axis and being bonded to each other, the composite having a thermal resistance value of not more than 10 mm²K/W measured on a surface parallel to an X-Z plane or a Y-Z plane.

With this configuration, the present composite has superior heat transfer efficiency.

### 1-1. Structure of Anisotropic Graphite Composite

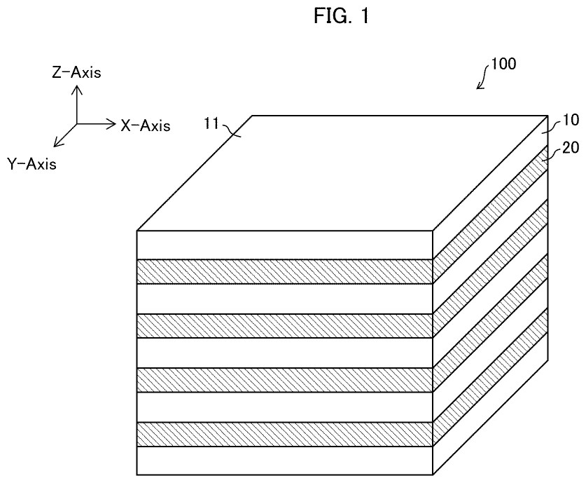

The structure of the present composite will be described in detail with reference to FIG. 1. FIG. 1 is a schematic diagram illustrating an outline of the structure of the present composite. As illustrated in FIG. 1, the present composite 100 includes (a) anisotropic graphite 10 and a (b) bonding layer 20 containing a metal and/or a resin. The (a) anisotropic graphite 10 has graphite layers whose respective crystal orientation planes 11 are parallel to an X-Y plane, given an X-axis, a Y-axis orthogonal to the X-axis, and a Z-axis perpendicular to the X-Y plane. The (a) anisotropic graphite 10 and the (b) bonding layer 20 containing the metal and/or the resin are alternately stacked in a direction of the Z-axis and bonded to each other.

### Thickness of Anisotropic Graphite Composite

The thickness of the present composite is not particularly limited, but is preferably not more than 1 mm, and more preferably not more than 0.5 mm. Controlling the thickness of the present composite to not more than 1 mm makes it possible to provide an anisotropic graphite composite having even superior heat transfer efficiency. The lower limit of the thickness of the present composite is not particularly limited, but may be not less than 0.01 mm, for example. As used herein, the thickness of the present composite refers to a thickness in a direction perpendicular to a cut surface formed in a cutting step described below (e. g., when a cut surface parallel to the X-Z plane is formed, the thickness refers to a thickness in the Y-axis direction, and when a cut surface parallel to the Y-Z plane is formed, the thickness refers to a thickness in the X-axis direction).

The thickness in the Z-axis direction of the (a) anisotropic graphite in the present composite (the thickness per layer of the (a) anisotropic graphite) is not particularly limited, but is preferably 10 μm to 1 mm from the viewpoint of providing a composite having even superior heat transfer efficiency, more preferably 50 μm to 500 μm, and even more preferably not less than 50 μm and not more than 300 μm.

The thickness in the Z-axis direction of the (b) bonding layer containing the metal and/or the resin in the present composite (the thickness per layer of the (b) bonding layer containing the metal and/or the resin) is not particularly limited, but is preferably 0.1 μm to 1 mm from the viewpoint of providing a composite having even superior heat transfer efficiency, more preferably 0.5 μm to 300 μm, and even more preferably not less than 1.0 μm and not more than 150 μm.

### 1-2. (a) Anisotropic Graphite

The present composite includes the (a) anisotropic graphite. As used herein, the (a) anisotropic graphite has a block-like structure in which multiple layers each having a graphite structure in which six-membered carbon rings are joined by covalent bonds (i.e., graphite layers) are stacked. The block-like (a) anisotropic graphite has high thermal conductivity in a direction parallel to a crystal orientation plane of the graphite layers. The word “anisotropic” in “anisotropic graphite” refers to the fact that, because the graphite layers have an orientation, the thermal conductivity of the anisotropic graphite differs greatly between a direction parallel to the crystal orientation planes of the graphite layers and a direction perpendicular to the crystal orientation planes.

The (a) anisotropic graphite in accordance with an embodiment of the present invention has a block-B230336/PCT like shape in which multiple layers each having a graphite structure in which six-membered rings are joined by covalent bonds (i. e., graphite layers) are stacked. The block-like (a) anisotropic graphite has high thermal conductivity in a direction parallel to a crystal orientation plane of the graphite layers.

The (a) anisotropic graphite in accordance with an embodiment of the present invention is not limited to a particular type of anisotropic graphite, provided that it has high thermal conductivity in a planar direction of the graphite structure in which six-membered rings are joined by covalent bonds. Specifically, examples which can be used as the (a) anisotropic graphite may include polymer-decomposed anisotropic graphite obtained by decomposing (e. g., pyrolysis) a polymer, graphene oxide, highly-oriented pyrolytic graphite (HOPG), pyrolytic anisotropic graphite obtained by treatment of kish graphite, extrusion molded anisotropic graphite obtained by subjecting expandable graphite to extrusion molding, molded anisotropic graphite obtained by subjecting expandable graphite to molding, and the like. Because the (a) anisotropic graphite has a high thermal conductivity in the planar direction of the graphite structure in which six-membered rings are joined by covalent bonds and the anisotropic graphite composite including the (a) anisotropic graphite has superior heat transfer performance, it is preferably to use polymer-decomposed anisotropic graphite or pyrolytic anisotropic graphite, or more preferably to use polymer-decomposed anisotropic graphite, as the (a) anisotropic graphite.

### Method of Producing Anisotropic Graphite

A method of producing the (a) anisotropic graphite in accordance with an embodiment of the present invention is not particularly limited. For example, a so-called polymer pyrolysis method may be adopted in which polymer films (e.g., polyimide films) are subjected to heat treatment in an inert gas atmosphere or under reduced pressure. In accordance with such a polymer pyrolysis method, polymer-decomposed anisotropic graphite can be produced. Examples of a more specific method of producing the (a) anisotropic graphite by the polymer pyrolysis method may include a method including a carbonizing step of heating a polymer film (e.g., polyimide film) at a temperature of about 1400° C., to obtain a carbonaceous film, a graphitizing step of subjecting the carbonaceous film obtained in the carbonizing step to heat treatment at a temperature of about 2900° C., to graphitize the carbonaceous film, so as to obtain anisotropic graphite in the form of a film, and a rolling step of rolling the obtained film-shaped anisotropic graphite.

### Carbonizing Step

The carbonizing step in the method of producing the (a) anisotropic graphite is a step of subjecting a polymer film to heat treatment at a temperature of about 1400° C., to carbonize the polymer film. The carbonizing step is preferably carried out in a vacuum atmosphere, under reduced pressure, or in an inert gas. Nitrogen is suitably used as the inert gas.

The temperature (maximum temperature) for heat treatment of the polymer film in the carbonizing step is, for example, preferably 1200° C. to 1600° C., and more preferably 1300° C. to 1500° C.

### Graphitizing Step

The graphitizing step of the (a) anisotropic graphite is a step of subjecting the carbonaceous film obtained in the carbonizing step to heat treatment at a temperature of about 2900° C., to graphitize the carbonaceous film. The graphitizing step is preferably carried out under reduced pressure or in an inert gas. Argon or helium may be suitably used as the inert gas, and a gas obtained by adding a small amount of helium to argon may be more preferably used.

In the graphitizing step, the temperature (maximum temperature) for heat treatment of the carbonaceous film obtained in the carbonizing step is, for example, preferably not less than 2400° C., preferably not less than 2600° C., preferably not less than 2800° C., preferably not less than 2900° C., or preferably not less than 3000° C. The upper limit of the maximum temperature is not particularly limited, but is preferably not more than 3300° C., and more preferably not more than 3200° C.

### Rolling Step

The rolling step in the method of producing the (a) anisotropic graphite is a step of rolling a film of anisotropic graphite obtained in the graphitizing step. In the present specification, a film of anisotropic graphite to be subjected to the rolling step, obtained in the graphitizing step, may be referred to as “anisotropic graphite film before rolling”, and a film of anisotropic graphite after being subjected to the rolling step may be referred to as “anisotropic graphite film after rolling”.

In the rolling step, the method of rolling an anisotropic graphite film is not particularly limited. Examples of the method may include, for example, a method of applying pressure using single-plate pressing or roll pressing.

### 1-3. (b) Bonding Layer Containing Metal and/or Resin

The present composite includes the (b) bonding layer containing a metal and/or a resin. As used herein, the “ (b) bonding layer containing a metal and/or a resin” may be referred to as “ (b) bonding layer”.

The (b) bonding layer may contain metal alone, resin alone, or both metal and resin.

The metal that may be contained in the (b) bonding layer is not particularly limited. However, the metal is preferably at least one selected from the group consisting of nickel, titanium, iron, chromium, tungsten, and stainless steel, because a part of each of these metals can be compatible with graphite at a high temperature, resulting in favorable bonding ability. The metal contained in the (b) bonding layer is particularly preferably nickel because it has strong bonding strength and superior heat transfer performance.

The resin that may be contained in the (b) bonding layer is not particularly limited. However, the resin is preferably at least one selected from the group consisting of an acrylic resin, a silicone resin, a urethane resin, a polyimide resin, a polyamide-imide resin, and an epoxy resin, because there is an advantage that these resins can easily exhibit adhesion to the graphite.

### 1-4. Physical Properties of Anisotropic Graphite Composite

### Thermal Resistance Value

The thermal resistance value of the present composite is not more than 10 mm²K/W. The thermal resistance value of the anisotropic graphite composite being not more than 10 mm²K/W implies that the present composite has superior heat transfer efficiency. A method of measuring the thermal resistance value of the anisotropic graphite composite used herein is as described in Examples.

The thermal resistance value of the present composite is not particularly limited, provided that it is not more than 10 mm²K/W. However, in terms of providing a composite having even superior heat transfer efficiency, the thermal resistance value is preferably not more than 9 mm²K/W, more preferably not more than 8 mm²K/W, and even more preferably not more than 7 mm²K/W, and particularly preferably not more than 6.5 mm²K/W. The lower limit of the thermal resistance value of the present composite is not particularly limited, but may be, for example, not less than 1 mm²K/W.

### 2. Method of Producing Anisotropic Graphite Composite

The following description will discuss a method of producing the anisotropic graphite composite in accordance with an embodiment of the present invention (which may be referred to as “the present production method” below). The present production method is a method of producing an anisotropic graphite composite including (a) anisotropic graphite and a (b) bonding layer containing a metal and/or a resin, the (a) anisotropic graphite having graphite layers whose respective crystal orientation planes are parallel to an X-Y plane, given an X-axis, a Y-axis orthogonal to the X-axis, and a Z-axis perpendicular to the X-Y plane, the method including: a bonding step of alternately stacking the (a) anisotropic graphite and the (b) bonding layer containing the metal and/or the resin in a direction of the Z-axis, and bonding them to each other; a cutting step of cutting a bonded body obtained in the bonding step; and a surface peeling step of peeling off a surface parallel to an X-Z plane or a Y-Z plane of the cut bonded body obtained in the cutting step.

A specific aspect of the (a) anisotropic graphite, and the (b) bonding layer containing the metal and/or the resin, used in the present production method is as described in the above Item “[1. Anisotropic graphite composite]”.

### 2-1. Bonding Step

The present production method includes the bonding step of alternately stacking the (a) anisotropic graphite and the (b) bonding layer containing the metal and/or the resin in the Z-axis direction, and bonding them to each other. The bonding step may also be described as a step of obtaining a bonded body of the anisotropic graphite to be subjected to the cutting step, that is, a bonded body before cutting.

The method of bonding a stack obtained by alternately stacking the (a) anisotropic graphite and the (b) bonding layer containing the metal and/or the resin in the Z-axis direction in the bonding step (which may be simply referred to as “stack”) is not particularly limited. However, a method of heating the stack while applying pressure with a load in the Z-axis direction may be suitably applied (hereafter, referred to as “Method A”).

### Stacking Method

In Method A, in a case where the metal forming the (b) bonding layer containing the metal and/or the resin, and the (a) anisotropic graphite are stacked, the metal may be stacked by (i) stacking it directly on the (a) anisotropic graphite. More specifically, the metal may be stacked on the (a) anisotropic graphite by any method such as an application method, a vacuum deposition method, a CVD method, and a spatter deposition method, or a metal sheet in the form of a sheet may be stacked.

Further, in Method A, in a case where a resin that forms the (b) bonding layer containing the metal and/or the resin, and the (a) anisotropic graphite are stacked, the resin may be stacked by applying it to the (a) anisotropic graphite, or a resin sheet in the form of a sheet may be stacked.

### Pressure

In Method A, the pressure applied to the stack is not particularly limited, provided that the (a) anisotropic graphite and the (b) bonding layer containing and the metal and/or the resin can be bonded thereby. For example, the pressure applied to the stack is preferably a load of 0.05 kg/cm² to 10 kg/cm², and more preferably a load of 0.1 kg/cm² to 5 kg/cm². By pressurizing with these pressures, it is possible to provide an anisotropic graphite composite having superior bonding strength between layers of the anisotropic graphite.

### Heating

In Method A, the stack is preferably heated in a vacuum, in an inert gas such as nitrogen and/or argon, in a reducing gas such as hydrogen, or in a mixed gas containing an inert gas and a reducing gas. In particular, it is preferable to carry out heating in Method A in an inert gas because this makes it possible to produce a stack without destroying the crystal structure of the anisotropic graphite, so that it is possible to provide an anisotropic graphite composite having superior thermal conductivity.

In Method A, the temperature at which the stack is heated is not particularly limited, but is preferably 700° C. to 1700° C., and more preferably 1000° C. to 1600° C. By heating the stack at these temperature, it is possible to provide an anisotropic graphite composite having superior bonding strength between layers of the anisotropic graphite.

### 2-2. Cutting Step

The present production method includes the cutting step of cutting the bonded body before cutting, obtained in the bonding step. The cutting step may also be described as a step of obtaining a bonded body of the anisotropic graphite to be subjected to the surface peeling step, that is, a bonded body after cutting. Further, the cutting step may also be described as a step of cutting the bonded body along a plane parallel to the X-Z plane or the Y-Z plane of the bonded body (that is, to form a cut surface parallel to the X-Z plane or the Y-Z plane) such that the thickness of the cut bonded body in a direction perpendicular to the X-Z plane or the Y-Z plane (that is, perpendicular to the cut surface) becomes a desired thickness.

In the cutting step, the method of cutting the bonded body before cutting is not particularly limited, and known techniques using a diamond cutter, a wire saw, a machining, or the like may be selected as appropriate. In the cutting step, it is preferable to cut the bonded body before cutting by using a wire saw because it is possible to easily provide a thinner (thin-film) bonded body and an anisotropic graphite composite.

In the cutting step, in a case where a wire saw is used to cut the bonded body before cutting, the bonded body before cutting is cut preferably at a cutting speed of not more than 1.0 mm/min and not less than 0.01 mm/min, and more preferably at a cutting speed of not more than 0.5 mm/min and not less than 0.01 mm/min. This makes it possible to reduce the formation of saw marks (uneven surface) on the cut surface of the cut bonded body (i.e., on the surface parallel to the X-Z plane or the Y-Z plane), resulting in a smoother cut surface. Thus, this makes it possible to provide an anisotropic graphite composite having even superior heat transfer efficiency.

### 2-3. Surface Peeling Step

The present production method includes the surface peeling step of peeling off a surface parallel to the X-Z plane or the Y-Z plane of the cut bonded body obtained in the cutting step. Herein, the surface parallel to the X-Z plane or the Y-Z plane of the cut bonded body is intended as a surface (cut surface) formed by cutting the bonded body in the cutting step. The surface peeling step may also be described as a step of obtaining an anisotropic graphite composite after surface peeling. The “anisotropic graphite composite” obtained by the present production method means this anisotropic graphite composite after surface peeling.

In the surface peeling step, the method of peeling off the surface of the cut bonded body is not particularly limited. Examples of the method of peeling may include a method in which a bonding tape, which can be easily peeled off, is stuck in tight contact on a surface of the anisotropic graphite composite before surface peeling (on a surface parallel to the X-Z plane or the Y-Z plane), and then the bonding tape is peeled off. The bonding tape that can be used in this method is not particularly limited, and common bonding tapes may be used. For example, mending tape manufactured by 3M Company, with an acrylic-based adhesive layer, polyimide tape with a silicone-based adhesive layer, or the like may be suitably used.

Through diligent research in order to provide anisotropic graphite composites having superior heat transfer efficiency, the inventors of the present invention found that a conventional anisotropic graphite composite (produced without carrying out the surface peeling step) has a surface on the X-Z plane or the Y-Z plane, which is a surface contacting the heat source, in which (i) the end portions of each graphite layer forming the anisotropic graphite composite present on the surface are covered by fine adhering matter, and (ii) the end portions are oriented in a direction substantially parallel to the X-Z plane or the Y-Z plane. The inventors of the present invention considered that these features (i) and (ii) reduce the heat transfer efficiency of the conventional anisotropic graphite composite, and the inventors conducted further diligent research in order to provide an anisotropic graphite composite in which these features (i) and (ii) have been addressed. As a result, it was found that, by carrying out the surface peeling step further after the cutting step, it was possible to (I) ) remove the fine adhering matter present on the surface of an anisotropic graphite composite before surface peeling, and (II) provide an anisotropic graphite composite in which the end portions of each graphite layer forming the anisotropic graphite composite are oriented in a substantially perpendicular direction, and it was also found that the anisotropic graphite composite after surface peeling had superior heat transfer efficiency. This has led to the completion of the present invention.

Thus, the anisotropic graphite composite (present composite) obtained by the present production method may also be described as an anisotropic graphite composite in which (I) almost no fine adhering matter is present on the surface of the X-Z plane or the Y-Z plane, and (II) the end portions of each graphite layer forming the anisotropic graphite composite are oriented in a substantially perpendicular direction.

The state of the end portions of each graphite layer forming the anisotropic graphite composite may be observed by using, for example, a scanning electron microscope (SEM).

### 3. Others

An embodiment of the present invention may include the following configurations.

<1> An anisotropic graphite composite comprising (a) anisotropic graphite and (b) a bonding layer containing a metal and/or a resin, the anisotropic graphite having graphite layers whose respective crystal orientation planes are parallel to an X-Y plane, given an X-axis, a Y-axis orthogonal to the X-axis, and a Z-axis perpendicular to the X-Y plane, the (a) anisotropic graphite and the (b) bonding layer containing the metal and/or the resin being alternately stacked in a direction of the Z-axis and being bonded to each other, the composite having a thermal resistance value of not more than 10 mm²K/W measured on a surface parallel to an X-Z plane or a Y-Z plane.

<2> The anisotropic graphite composite according to <1>, wherein the metal is at least one selected from the group consisting of nickel, titanium, iron, chromium, tungsten, and stainless steel.

<3> The anisotropic graphite composite according to <1>, wherein the resin is at least one selected from the group consisting of an acrylic resin, a silicone resin, a urethane resin, a polyimide resin, a polyamide-imide resin, and an epoxy resin.

<4> The anisotropic graphite composite according to any one of <1> to <3>, wherein the thermal resistance value is not more than 8 mm²K/W.

<5> The anisotropic graphite composite according to any one of <1> to <4>, wherein the (a) anisotropic graphite is polymer-decomposed anisotropic graphite or pyrolytic anisotropic graphite.

<6> A method of producing an anisotropic graphite composite comprising (a) anisotropic graphite and a (b) bonding layer containing a metal and/or a resin, the (a) anisotropic graphite having graphite layers whose respective crystal orientation planes are parallel to an X-Z plane, given an X-axis, a Y-axis orthogonal to the X-axis, and a Z-axis perpendicular to the X-Y plane, the method comprising: a bonding step of alternately stacking the (a) anisotropic graphite and the (b) bonding layer containing the metal and/or the resin in a direction of the Z-axis, and bonding them to each other; a cutting step of cutting an obtained bonded body; and a surface peeling step of peeling off a surface parallel to an X-Z plane or a Y-Z plane of the cut bonded body obtained in the cutting step.

<7> The method of producing the anisotropic graphite composite according to <6>, wherein the cutting step includes a step of cutting the anisotropic graphite composite by using a wire saw under a condition of a cutting speed of not more than 1.0 mm/min.

<8> The method of producing the anisotropic graphite composite according to <6> or <>>, wherein the metal is at least one selected from the group consisting of nickel, titanium, iron, chromium, tungsten, and stainless steel.

<9> The method of producing the anisotropic graphite composite according to any one of <6> to <8>, wherein the resin is at least one selected from the group consisting of an acrylic resin, a silicone resin, a urethane resin, a polyimide resin, a polyamide-imide resin, and an epoxy resin.

<10> The method of producing the anisotropic graphite composite according to any one of <6> to <9>, wherein the (a) (anisotropic graphite is polymer-decomposed anisotropic graphite or pyrolytic anisotropic graphite.

### EXAMPLES

The following description will discuss an embodiment of the present invention through Examples and Comparative Examples; however, the technical scope of the present invention is not limited to these Examples.

### Method of Measuring Thermal Resistance Value

The method of measuring the thermal resistance values of composites and bonded bodies obtained in Examples and Comparative Examples was as follows: a sample of 10 mm in length and 10 mm in width was cut out from each of the obtained composites or bonded bodies having desired thicknesses. Each of the resultant samples was held between probes under the conditions of a sample temperature of 50° C. and a constant load mode of 20 N, using a resin thermal resistance measuring device (manufactured by Hitachi Technologies and Services, Ltd.), and the thermal resistance value (thermal resistance value in the thickness direction of the composite or the bonded body) was then measured.

### Example 1

By alternately stacking 100 polyimide films (Apical NPI, manufactured by Kaneka Corporation) each having a thickness of 75 um and dimensions of 250 mm in length and 310 mm in width, and 100 natural graphite sheets each having a thickness of 200 um and dimensions of 260 mm in length and 320 mm in width, a stack of a thickness of 27.5 mm was obtained. The resultant stack was placed under a graphite load plate, and then set in a carbonization furnace with a load of 5 g/cm² applied, heated at a heating rate of 0.5 ° C./min to 1400° C., and held at 1400 ° C. for 10 minutes, to carbonize the polyimide films, resulting in carbonized films.

Subsequently, the resultant 100 carbonized films were stacked alternately with natural graphite sheets each having a thickness of 200 μm and dimensions of 260 mm in length and 320 mm in width, resulting in a stack with a thickness of 27.5 mm. The resultant stack was placed under a graphite load plate, and then set in a graphitization furnace with a load of 5 g/cm² applied, heated at a heating rate of 3.3 ° C./min to 2900° C., and held at 2900° C. for 10 minutes, to graphitize the carbonized films, resulting in anisotropic graphite films.

The resultant 100 anisotropic graphite films (thickness of 300 μm) were stacked and rolled by applying a pressure of 20 MPa at room temperature using a single-plate pressing with the stack sandwiched between polyimide films, Teflon (registered trademark) films, cushioning rubber components, and iron plates on both the top and bottom sides, to obtain anisotropic graphite films after rolling (200 μm thickness).

The resultant anisotropic graphite films after rolling were cut out of 400 sheets with dimensions of 40 mm in length and 40 mm in width. The 400 sheets of the anisotropic graphite film, and 399 sheets of nickel foil each having a thickness of 5 um and dimensions of 40 mm in length and 40 mm in width were alternately stacked, to obtain a stack. The stack was heated, while applying a pressure of 0.4 kg/cm² in argon gas, at a heating rate of 2.0° C./min to 1340° C. and held at 1340° C. for 30 minutes, so that the anisotropic graphite film and the nickel foil were bonded by thermal bonding, to produce an anisotropic graphite/nickel bonded body A-1 (thickness of 60 mm; dimensions of 40 mm in length and 40 mm in width) in which the layers of the anisotropic graphite and the bonding layers consisting of nickel were alternately stacked. For the resultant bonded body A-1, a plane parallel to the crystal orientation planes of the graphite layers of the anisotropic graphite was defined as the X-Y plane, and the thickness direction was defined as the Z-axis.

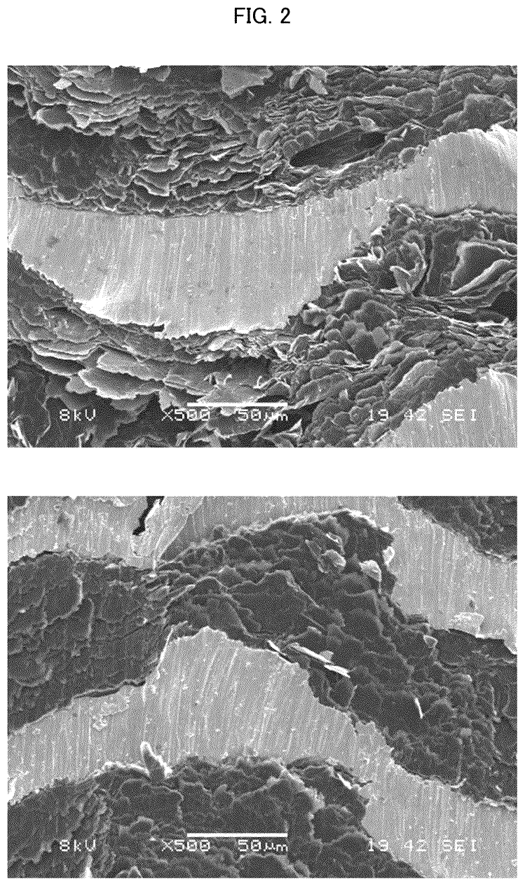

The resultant bonded body A was cut in a direction parallel to the Y-Z plane by using a wire saw (Type WSD-K2, manufactured by Takatori Corporation) at a cutting speed of 0.5 mm/min, to obtain an anisotropic graphite/nickel bonded body B-1 (cut bonded body) with a thickness of 0.25 mm (X-axis) and dimensions of 40 mm in length (Y-axis) and 60 mm in width (Z-axis) (cutting step). The bonded body B-1 was then cut into a sample having a thickness of 0.25 mm (X-axis direction) and dimensions of 10 mm in length (Y-axis) and 10 mm in width (Z-axis). The thermal resistance value (thermal resistance value in the X-axis direction) of the resultant sample of the bonded body B-1 was measured. The thermal resistance value was 10.8 mm²K/W. Then, a surface of the bonded body B-1 that is parallel to the Y-Z plane was observed by using a scanning electron microscope (SEM). An image obtained by SEM at a magnification of 500× is shown in FIG. 2 (upper image). As shown in FIG. 2 (upper image), on the surface parallel to the Y-Z plane of the bonded body B-1, the end portion of the graphite forming each graphite layer was coated with fine adhering matter, and the end portion was oriented in a direction substantially parallel to the Y-Z plane.

To this sample of the bonded body B-1, a mending tape (manufactured by 3M Company) was attached on each of opposite surfaces parallel to the Y-Z plane and the tape was carefully peeled off, to obtain an anisotropic graphite/nickel composite C-1 (graphite composite after surface peeling) (surface peeling step). The thermal resistance value (thermal resistance value in the X-axis direction) of the resultant composite C-1was measured. The thermal resistance value was 5.7 mm²K/W. Then, a surface of the composite C-1 that is parallel to the Y-Z plane was observed by using a scanning electron microscope (SEM). An image obtained by SEM at a magnification of 500× is shown in FIG. 2 (lower image). As shown in FIG. 2 (lower image), on the surface parallel to the Y-Z plane of the composite C-1, the end portion of the graphite forming each graphite layer was oriented in a direction substantially perpendicular to the Y-Z plane.

### Example 2

The bonded body A-1 obtained in Example 1 was cut in a direction parallel to the Y-Z plane by using a wire saw (Type WSD-K2, manufactured by Takatori Corporation) at a cutting speed of 0.5 mm/min, to obtain an anisotropic graphite/nickel bonded body B-2 with a thickness of 0.30 mm (X-axis) and dimensions of 40 mm in length (Y-axis) and 60 mm in width (Z-axis) (cutting step). Visual inspection of the cross-section of the obtained bonded body B-2 revealed no saw mark caused by the wire saw. The bonded body B-2 was then cut into a sample having a thickness of 0.30 mm (X-axis) and dimensions of 10 mm in length (Y-axis) and 10 mm in width (Z-axis). The thermal resistance value (thermal resistance value in the X-axis direction) of the resultant sample of the bonded body B-2 was measured. The thermal resistance value was 15.0 mm²K/W.

To this sample of the bonded body B-2, a mending tape (manufactured by 3M Company) was attached on each of opposite faces of the surfaces parallel to the Y-Z plane and the tape was carefully peeled off, to obtain an anisotropic graphite/nickel composite C-2 (graphite composite after surface peeling) (surface peeling step). The thermal resistance value (thermal resistance value in the X-axis direction) of the resultant composite C-2 was measured. The thermal resistance value was 6.2 mm²K/W. The results are shown in Table 1. Then, a surface of the composite C-2 that is parallel to the Y-Z plane was observed by using a scanning electron microscope (SEM). On the surface parallel to the Y-Z plane of the composite C-2, the end portion of the graphite forming each graphite layer was oriented in a direction substantially perpendicular to the Y-Z plane (not illustrated).

### Comparative Example 1

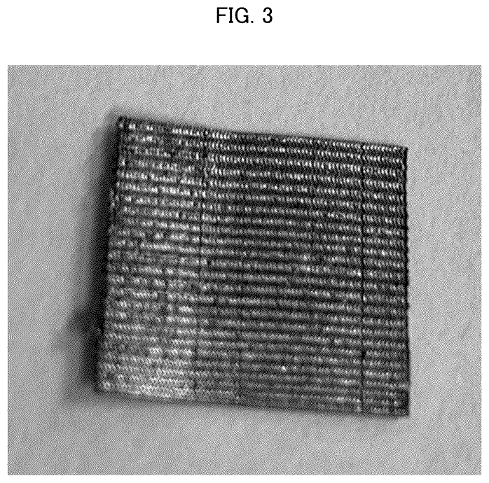

The bonded body A-1 obtained in Example 1 was cut in a direction perpendicular to the X-axis by using a wire saw (Type WSD-K2, manufactured by Takatori Corporation) at a cutting speed of 1.5 mm/min, to obtain an anisotropic graphite/nickel bonded body B-3 with a thickness of 0.40 mm (X-axis) and dimensions of 40 mm in length (Y-axis) and 60 mm in width (Z-axis). FIG. 3 shows the results of a visual inspection of the cut surface of the bonded body B-3 obtained. As shown in FIG. 3, saw marks caused by the wire saw were observed on the cut surface of the bonded body B-3. The bonded body B-3 was further cut into a sample having a thickness of 0.40 mm (X-axis) and dimensions of 10 mm in length (Y-axis) and 10 mm in width (Z-axis). The thermal resistance value (thermal resistance value in the X-axis direction) of the resultant sample of the bonded body B-3 was measured. The thermal resistance value was 24.6 mm²K/W.

Aspects of the present invention can also be expressed as follows:
Each of the composites of Examples 1 and 2 obtained in the cutting step and the surface peeling step had a thermal resistance value of not more than 10 mm²K/W, indicating that these composites had superior heat transfer performance. On the other hand, it can be apparent from Comparative Example 1 that the heat transfer performance of a composite obtained without the surface peeling step becomes poor.

### INDUSTRIAL APPLICABILITY

According to an embodiment of the present invention, it is possible to provide an anisotropic graphite composite having superior heat transfer efficiency. This anisotropic graphite composite can be suitably applied in fields such as electronic equipment and electronic parts.

### REFERENCE SIGNS LIST

10 Anisotropic graphite
11 Crystal orientation plane of graphite layer of anisotropic graphite
20 Bonding layer
100 Anisotropic graphite composite

1. An anisotropic graphite composite comprising:
anisotropic graphite; and
a bonding layer including at least one of a metal or a resin,
the anisotropic graphite having graphite layers whose respective crystal orientation planes are parallel to an X-Y plane, given an X-axis, a Y-axis orthogonal to the X-axis, and a Z-axis perpendicular to the X-Y plane,
the anisotropic graphite and the bonding layer being alternately stacked in a direction of the Z-axis and being bonded to each other, and
the anisotropic graphite composite having a thermal resistance value of not more than 10 mm²K/W measured on a surface parallel to an X-Z plane or a Y-Z plane.

2. The anisotropic graphite composite according to claim 1, wherein the metal is at least one selected from the group consisting of nickel, titanium, iron, chromium, tungsten, and stainless steel.

3. The anisotropic graphite composite according to claim 1, wherein the resin is at least one selected from the group consisting of an acrylic resin, a silicone resin, a urethane resin, a polyimide resin, a polyamide-imide resin, and an epoxy resin.

4. The anisotropic graphite composite according to claim 1, wherein the thermal resistance value is not more than 8 mm²K/W.

5. The anisotropic graphite composite according to claim 1, wherein the anisotropic graphite is polymer-decomposed anisotropic graphite or pyrolytic anisotropic graphite.

6. A method of producing an anisotropic graphite composite comprising anisotropic graphite and a bonding layer including at least one of a metal or a resin,
the anisotropic graphite having graphite layers whose respective crystal orientation planes are parallel to an X-Y plane, given an X-axis, a Y-axis orthogonal to the X-axis, and a Z-axis perpendicular to the X-Y plane,
the method comprising:
alternately stacking the anisotropic graphite and the bonding layer in a direction of the Z-axis, and bonding them to each other to create a bonded body;
cutting the bonded body obtained by the bonding-step; and
peeling off a surface parallel to an X-Z plane or a Y-Z plane of the cut bonded body obtained in the cutting.

7. The method of producing the anisotropic graphite composite according to claim 6, wherein the cutting includes cutting the bonded body by using a wire saw under a condition of a cutting speed of not more than 1.0 mm/min.

8. The method of producing the anisotropic graphite composite according to claim 6, wherein the metal is at least one selected from the group consisting of nickel, titanium, iron, chromium, tungsten, and stainless steel.

9. The method of producing the anisotropic graphite composite according to claim 6, wherein the resin is at least one selected from the group consisting of an acrylic resin, a silicone resin, a urethane resin, a polyimide resin, a polyamide-imide resin, and an epoxy resin.

10. The method of producing the anisotropic graphite composite according to claim 6, wherein the anisotropic graphite is polymer-decomposed anisotropic graphite or pyrolytic anisotropic graphite.
